(19) United States
(12) Patent Application Publication
(10) Pub. No.: US 2022/0128353 A1
(43) Pub. Date: Apr. 28, 2022

(54) Structural Health Monitoring Method and System

(71) Applicant: AGENCY FOR SCIENCE, TECHNOLOGY AND RESEARCH, Singapore (SG)

(72) Inventors: Huajun Liu, Singapore (SG); Kui Yao, Singapore (SG); Lei Zhang, Singapore (SG)

(21) Appl. No.: 17/436,128

(22) PCT Filed: Mar. 16, 2020
(86) PCT No.: PCT/SG2020/050138

§ 371 Date: Sep. 3, 2021

(30) Foreign Application Priority Data
Mar. 20, 2019 (SG) 10201902500Q

(51) Int. Cl. G01B 17/04; H01L 41/08; H01L 41/314; H01L 41/29; G01N 29/04; G01B 11/16

(52) U.S. Cl. CPC G01B 17/04; H01L 41/0805; H01L 41/314; H01L 41/18; G01N 29/043; G01B 11/162; H01L 41/29

(57) ABSTRACT

A structural health monitoring method includes directly forming an acoustic transducer on a surface of a structure to be monitored; generating, by the acoustic transducer, an acoustic wave to apply stress loading to a region of interest on the structure; and detecting a presence of a defect in the region of interest. Detecting includes a non-contact optical imaging of the region of interest with and without the stress loading and an analysis of imaging data from the non-contact optical imaging.

### TECHNICAL FIELD

The present disclosure relates broadly, but not exclusively, to structural health monitoring methods and systems.

### BACKGROUND

It is vital to ensure the critical structures in aerospace, marine-offshore, transportation applications and in buildings, for example, are in good operating conditions to avoid catastrophic structural failures. Structural health monitoring (SHM) can provide a solution to this problem as it can detect integrity and damage conditions of critical structures in a non-destructive way and at repeated intervals. SHM is also able to indicate the useful lifetime of these critical structures as it provides the information of the conditions over a long period of time. The recent integration of SHM with internet of things (IoT) is promising for remote, continuous and accurate monitoring of these critical structures and living environment, enabling the vision of a smart city.

Current SHM technologies are based on vibration, ultrasound, eddy-current, radiography and optical interferometry. However, each of these technologies has its limitations. For example, vibration-based SHM method measures the change of natural vibration frequencies of testing structures when damages are developed in the structures. However, the interpretation of the testing results is difficult due to the complexity of testing structures and the influence of multiple materials parameters. Moreover, the response is from overall structure, thus it is difficult to locate the position of damage.

Ultrasound-based SHM method detects damage by measuring the change of the amplitude and/or frequency of ultrasonic waves due to the presence of defects. However, the ultrasonic testing with discrete ultrasound probes is usually time-consuming due to transducer set-up and point-by-point scanning. In addition, the interpretation of testing results requires substantial expertise due to the fact that complex multiple factors could contribute to the change of ultrasonic waves.

Eddy-current based SHM method detects the change of eddy-current induced by electromagnetic induction for electrically conductive structures under test. It is limited mostly to metallic structures and is not applicable to electrically non-conducting structures. Furthermore, the detection of eddy-current is limited to the surface, due to the shielding of the magnetic field by the surface layer.

Radiography-based SHM method images the internal defects of the structures by transmitting X-ray or y-ray through the structures under test. However, due to the safety concerns of radioactivity, it cannot be used to do on-site testing in most cases. Moreover, some structures are not accessible on both sides, preventing the transmission testing geometry of radiography.

Optical interferometry, such as holography and shearography, images the surface displacement or displacement gradient by lasers when the structures under test are under loading and non-loading conditions. As the optical method is sensitive to surface changes, the detection depth is generally very limited using conventional loading methods.

A need therefore exists to provide structural health monitoring methods and systems that can address at least some of the limitations of the conventional techniques, or provide a useful alternative.

### SUMMARY

An aspect of the present disclosure provides a structural health monitoring method comprising:

directly forming an acoustic transducer on a surface of a structure to be monitored;

generating, by the acoustic transducer, an acoustic wave to apply stress loading to a region of interest on the structure; and

detecting a presence of a defect in the region of interest, wherein detecting comprises a non-contact optical imaging of the region of interest with and without the stress loading and an analysis of imaging data from the non-contact optical imaging.

Directly forming the acoustic transducer may comprise:

directly forming a piezoelectric layer on the surface of the structure;

patterning a plurality of electrodes on the piezoelectric layer; and

selecting a periodicity of the electrodes based on a wavelength of the acoustic wave.

The method may further comprise forming the plurality of electrodes as concentric curves, and selecting a center of the concentric curves to coincide with the region of interest.

The transducer may comprise a phased-array transducer comprising a plurality of elements, and generating the acoustic wave may comprise controlling a time delay between the elements to tune a penetration depth of the acoustic wave in the region of interest.

Generating the acoustic wave may further comprise activating selected elements of the plurality of elements.

The method may further comprise directly forming a plurality of acoustic transducers on the surface of the structure and simultaneously generating a plurality of acoustic waves corresponding to the acoustic transducers to detect the presence of one or more defects.

Directly forming the piezoelectric layer on the surface of the structure may comprise depositing a piezoelectric ceramic layer on the surface of the structure by a thermal spray process.

Directly forming the piezoelectric layer on the surface of the structure may comprise depositing a piezoelectric polymer layer on the surface of the structure by an aerosol spray process.

The non-contact optical imaging of the structure may comprise shearography imaging.

The non-contact optical imaging of the structure may comprise holographic imaging.

The non-contact optical imaging of the structure may comprise optical metrology.

Another aspect of the present disclosure provides a structural health monitoring system comprising:

an acoustic transducer formed directly on a surface of a structure to be monitored;

a non-contact optical imaging device configured to image a region of interest on the structure; and

a processor communicatively coupled to the acoustic transducer and the non-contact optical imaging device,

wherein the acoustic transducer is configured to generate an acoustic wave to apply stress loading to the region of interest, and wherein the processor is configured to receive imaging data of the region of interest from the non-contact optical imaging device with and without the stress loading and to analyse the imaging data to detect a presence of a defect in the region of interest.

The acoustic transducer may comprise a piezoelectric layer and a plurality of electrodes patterned on the piezoelectric layer, and a periodicity of the electrodes may be selected based on a wavelength of the acoustic wave.

The plurality of electrodes may comprise concentric curves, and a center of the concentric curves may be selected to coincide with the region of interest.

The transducer may comprise a phased-array transducer comprising a plurality of elements, and the processor may be further configured to control a time delay between the elements to tune a penetration depth of the acoustic wave in the region of interest.

The processor may be further configured to activate selected elements of the plurality of elements to generate the acoustic wave.

The system may comprise a plurality of acoustic transducers directly formed on the surface of the structure and communicatively coupled to the processor, and the plurality of acoustic transducers may be configured to simultaneously generate a plurality of acoustic waves to detect the presence of one or more defects.

The piezoelectric layer may comprise a piezoelectric ceramic layer.

The piezoelectric layer may comprise a piezoelectric polymer layer.

The non-contact optical imaging device may comprise a shearography imaging device.

The non-contact optical imaging device may comprise a holographic imaging device.

The non-contact optical imaging device may comprise an optical metrology device.

### BRIEF DESCRIPTION OF THE DRAWINGS

Embodiments of the disclosure will be better understood and readily apparent to one of ordinary skill in the art from the following written description, by way of example only, and in conjunction with the drawings, in which:

FIGS. 1(a) and 1(b) show optical images of front and back sides, respectively, of a structure with an acoustic transducer directly formed thereon according to an example embodiment.

FIGS. 1(c) and 1(d) show graphs of dielectric loss and displacement amplitude, respectively, of the structure of FIGS. 1(a) and 1(b) at different frequencies.

FIG. 2(a) shows a schematic diagram of a system for structural health monitoring according to an example embodiment.

FIG. 2(b) shows a shearography image obtained from the system of FIG. 2(a).

FIG. 3 shows a schematic diagram of an acoustic transducer according to an example embodiment.

FIGS. 4(a) and 4(b) show schematic diagrams of phased-array acoustic transducers according to example embodiments.

FIG. 5 shows a schematic diagram illustrating tuning a penetration depth of the acoustic wave using a phased-array acoustic transducer such as ones of FIGS. 4(a) and 4(b).

FIG. 6 shows a schematic diagram illustrating using multiple acoustic transducers to simultaneously detect one or more defects according to an example embodiment.

FIG. 7 shows a flow chart illustrating a structural health monitoring method according to an example embodiment.

Skilled artisans will appreciate that elements in the figures are illustrated for simplicity and clarity and have not necessarily been depicted to scale. For example, the dimensions of some of the elements in the illustrations, block diagrams or flowcharts may be exaggerated in respect to other elements to help to improve understanding of the present embodiments.

### DETAILED DESCRIPTION

The present disclosure provides methods and systems for structural health monitoring that use acoustic transducers in the form of piezoelectric transducers directly formed on a structure to be monitored (e.g. by direct-writing) to generate acoustic waves as stress loading method, and a non-contact optical imaging method to detect defects in the structure.

As described in further details below, piezoelectric transducers are directly formed (e.g. directly written) on the structures under test by thermal spray or aerosol spray coating. Directly written transducers can generate acoustic waves that act as stress loading, inducing surface deformation anomaly around defects which can be captured by non-contact optical-based imaging methods.

In example embodiments, the piezoelectric transducers include a piezoelectric layer formed directly on the surface of the structure to be monitored (hereinafter interchangeably referred to as structure under test), and electrodes patterned on the piezoelectric layer. For a piezoelectric polymer material, the method of direct-writing the piezoelectric layer includes an aerosol spray, while for a piezoelectric ceramic material, the method of direct-writing the piezoelectric layer includes a thermal spray. Direct-writing of piezoelectric materials onto the structure, applicable over a large area, can avoid the inconsistent and time-consuming bonding process of conventional multiple discrete transducers.

To generate large surface displacements for detection by shearography, in some examples, piezoelectric ceramics with high piezoelectric coefficient and low dielectric loss may be preferred. The direct-writing of piezoelectric ceramics may include heating the ceramic powders to a partially molten state, depositing the partial molten ceramics on the structure to be monitored, re-crystallizing to desired crystalline phase of piezoelectric ceramics during cooling down, followed by an optional heat treatment to further enhance the crystallinity. The coated piezoelectric ceramic layer typically has a thickness of a few hundred micrometers.

The directly written transducers may have various configurations and geometries. One example is a single-element transducer having multiple fingers with finger periodicity matching the acoustic wavelength to enhance acoustic energy at the region of interest. Another example is a concentric comb pattern that geometrically focuses acoustic waves to enhance acoustic energy in particular directions. Another example is a multi-element phased-array transducer that concentrates acoustic energy at a certain penetration depth, which is tunable by controlling the time delay between the elements. In yet another example, the directly written transducers can be patterned at multiple locations for simultaneous detection of multiple defects.

The non-contact detection system measures surface displacement anomaly induced by the interaction of the acoustic wave and defects. The non-contact detection system can be a shearography, a holography or an optical metrology system.

For example, shearography is a full-field imaging method that can detect the defects by comparing the optical interferometric image of the testing structure under loading and unloading conditions (i.e. with and without load). As acoustic waves can penetrate deep into the structure to be monitored, the acoustic wave based loading method is able to detect sub-surface defects of approximately 10 mm. The directly written transducers with different designs in the present disclosure are able to focus the acoustic waves to desired directions and depth to effectively detect both surface and sub-surface defects by shearography and other non-contact optical imaging methods.

In other words, in embodiments in the present disclosure, the use of directly-formed ultrasonic transducers made of piezoelectric coating in one batch not only can provide the benefits of consistency and quick deployment, but also allow generation of acoustic waves as stress loading that covers a large area. Furthermore, the proper configuration and design of the directly-formed transducers can enhance the acoustic energy at desired regions to enable defect detection by non-contact optical imaging.

Embodiments will be described, by way of example only, with reference to the drawings. Like reference numerals and characters in the drawings refer to like elements or equivalents.

FIGS. 1(a) and 1(b) show optical images of front and back sides, respectively, of a structure 100 with an acoustic transducer 102 directly formed thereon according to an example embodiment. In this example, the structure 100 is in the form of a stainless steel plate, and an oxide thermal barrier coating 104 is first deposited on the stainless steel plate to prevent inter-diffusion between the piezoelectric coating material and the stainless steel and to promote the crystallinity of the piezoelectric material. A potassium sodium niobate (K,Na)NbO₃ based lead-free piezoelectric coating material 106 is coated on top of the thermal barrier coating by a thermal spray process. The electrodes 108a, 108b, 108b, 108d are patterned on top of the piezoelectric layer 106, forming multiple fingers with finger periodicity selected to generate acoustic waves of 400 kHz. Four notches 110a, 110b, 110c, 110d, which are not visible from the front side in FIG. 1(a), are created on the back side of the stainless steel plate, as shown in FIG. 1(b). As examples, the length of the notches 110a, 110b, 110c, 110d is 5 mm, the width is 0.5 mm and the depth is varied from 0.5 mm, 1 mm, 1.5 mm and 2 mm.

FIGS. 1(c) and 1(d) show graphs of dielectric loss and displacement amplitude, respectively, of the structure of FIGS. 1(a) and 1(b) at different frequencies. The dielectric and piezoelectric properties of the directly written piezoelectric transducer 102 is characterized by impedance spectroscopy and laser scanning vibrometer, as shown in FIGS. 1(c) and 1(d) respective. At 200 kHz, the dielectric loss is approximately 4% and the piezoelectric coefficient is approximately 41 pm/V.

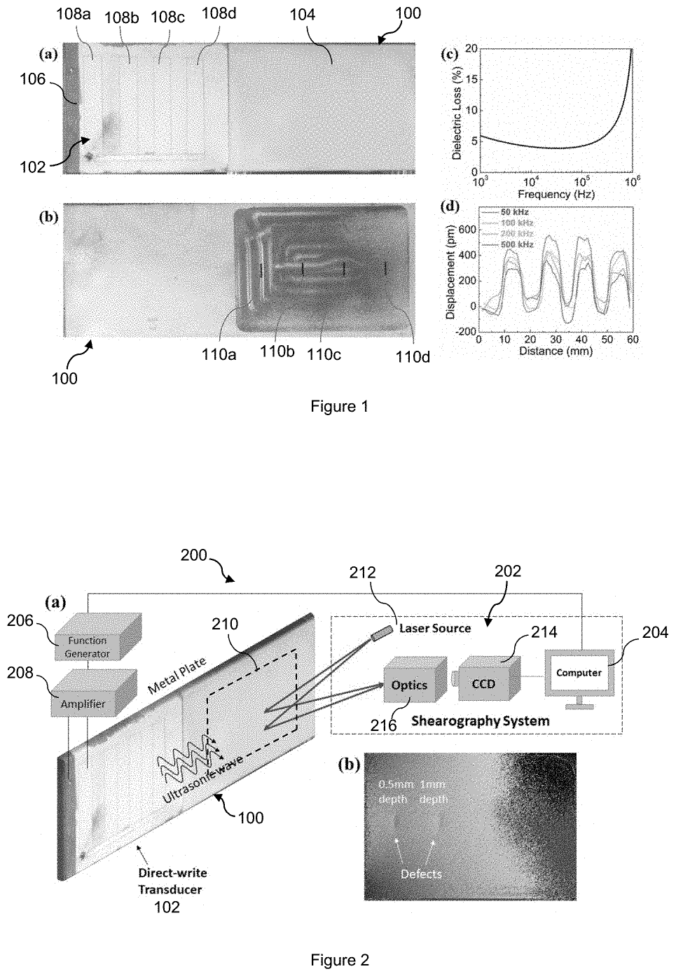

FIG. 2(a) shows a schematic diagram of a system 200 for structural health monitoring according to an example embodiment. FIG. 2(b) shows a shearography image obtained from the system 200 of FIG. 2(a).

System 200 includes an acoustic transducer formed directly on a surface of a structure to be monitored. In FIG. 2(a), the structure to be monitored is the structure 100 as described above with reference to FIGS. 1(a) and 1(b), and the acoustic transducer 102 is directly written on a surface of the structure 100 as described above. System 200 also includes a non-contact optical imaging device 202 and a processor in the form of a computer 204. The computer 204 is communicatively coupled to the acoustic transducer 102 via a function generator 206 and power amplifier 208 and to the non-contact optical imaging device 202. In other words, the computer 204 controls both the transducer 102 and the imaging device 202. The non-contact imaging device 202 is configured to image a region of interest 210 on the structure 100. In this example, the non-contact imaging device 202 is a shearography imaging device and includes a laser source 212, an optical sensor in the form of a charge coupled device (CCD) camera 214, and associated optics 216.

In use, the acoustic transducer 102 can generate an acoustic wave to apply stress loading to the region of interest 210. The processor/computer 204 receives imaging data of the region of interest 210 from the non-contact optical imaging device 202 with and without the stress loading and analyses the imaging data to detect a presence of a defect in the region of interest 210.

In one implementation, the transducer 102 is driven by the function generator 206 and power amplifier 208 controlled by the computer 204 at 200 kHz and 100 V in amplitude to generate acoustic waves to interact with sub-surface defects (e.g. the four notches 110a, 110b, 110c, 110d shown in FIG. 1(b)). The laser source 212 shines on the region of interest 210 on the structure 100 from the front side where the notches are not visible. The reflected laser speckle pattern is collected by the CCD camera 214 after going through an optical interferometer of the optics 216 and recorded in the controlling computer 204. The shearography image taken is shown in FIG. 2(b). Two defects with depth of 0.5 mm and 1 mm can be clearly observed in the image. Deeper defects may be observed at higher driving power, using directly written transducers with varied designs, or using a piezoelectric material with higher piezoelectric coefficients.

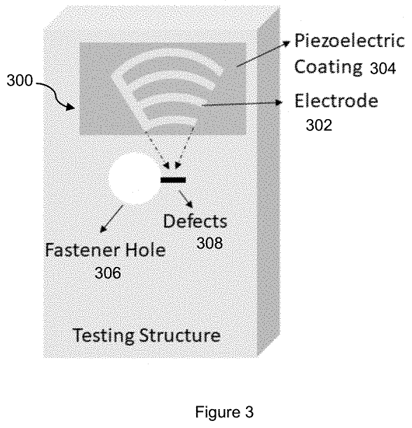

The acoustic transducer in the present disclosure may have various patterns and geometries. FIG. 3 shows a schematic diagram of an acoustic transducer 300 according to an example embodiment. In this example, the transducer 300 is directly written and has concentric comb pattern of curved electrodes 302 formed on a piezoelectric coating 304. The curved electrodes 302 are concentric about a common center, which is selected to coincide with the region of interest. For example, as shown in FIG. 3, the transducer 300 can geometrically focus the acoustic waves to the region around the fastener hole 306, where defects 308 are most likely to develop. This configuration can help to focus acoustic energy to the region of interest, allowing detection of smaller and deeper defects.

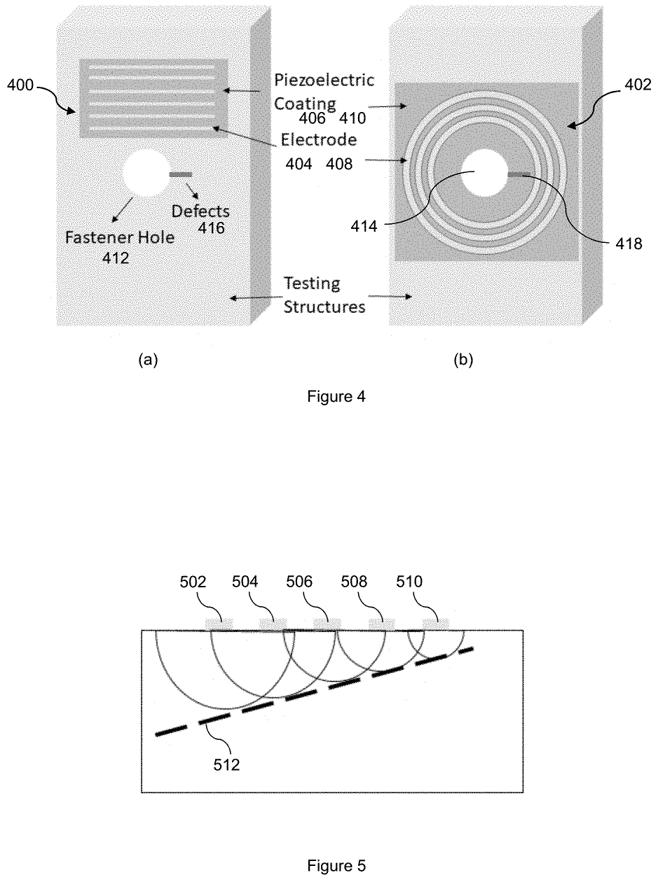

FIGS. 4(a) and 4(b) show schematic diagrams of phased-array acoustic transducers 400, 402 according to other example embodiments. In these examples, the transducers 400, 402 are patterned as multi-element phased array transducers. Transducer 400 has electrodes 404 forming a line pattern on a piezoelectric coating 406, while transducer 402 has electrodes 408 forming a circular pattern on a piezoelectric coating 410. Due to the focusing of acoustic energy into a desired region of interest, the surface displacement can be significantly improved, thus giving rise to better sensitivity of shearography images to small defects. For example, as shown in FIGS. 4(a) and 4(b), the transducers 400, 402 can geometrically focus the acoustic waves to the region around the fastener holes 412, 414 respectively where defects 416, 418 are most likely to develop.

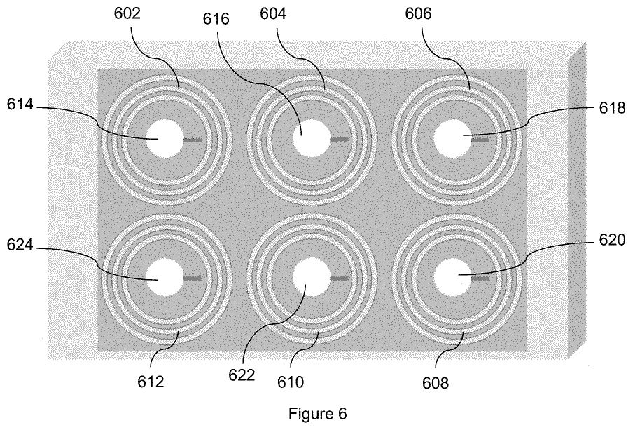

The acoustic waves generated by the multi-element phased array transducers 400, 402 in FIGS. 4(a) and (4b) can be steered to a certain penetration depth by controlling excitation of each piezoelectric element. FIG. 5 shows a schematic diagram illustrating tuning a penetration depth of the acoustic wave using a phased-array acoustic transducer like ones in FIGS. 4(a) and 4(b). For example, the element 502 on the left is selectively driven first and other elements 504, 506, 508, 510 are driven later in sequence to the right, so that the acoustic wave fronts are inclined to the left side. The inclination angle (formed by line 512) can be changed to focus acoustic wave to a different depth, which can be tuned electrically by changing the driving order and time delay among the piezoelectric elements.

In some embodiments, a combination of multiple acoustic transducers may be disposed on the surface of the structure to be monitored, for example, in applications with multiple structural features over a large area. The multiple transducers can be activated to generate a plurality of acoustic waves to simultaneously detect the presence of one or more defects. FIG. 6 shows a schematic diagram multiple acoustic transducers being used to simultaneously detect one or more defects according to an example embodiment. In this example, the directly written acoustic transducers 602, 604, 606, 608, 610, 612 are patterned at multiple regions of interest. In the case of an array of fastener holes 614, 616, 618, 620, 622, 624 in the structure under test, the piezoelectric transducers 602, 604, 606, 608, 610, 612 can be directly written over a large area covering all the holes 614, 616, 618, 620, 622, 624, as shown in FIG. 6. Alternatively or in addition, multiple electrode patterns can be written near each fastener hole to simultaneously detect the defects by shearography during a short time. Also, while the acoustic transducers 602, 604, 606, 608, 610, 612 are each shown to have a circular pattern in FIG. 6, it will be appreciated that a combination of different transducer geometries may be used in alternate embodiments.

In the examples described above, the non-contact optical imaging comprises shearography imaging which can provide full-field visualisation, but other imaging methods, for example, holographic interferometry or optical metrology can also be used in alternate embodiments. For holographic imaging, the structure under test is first imaged by lasers to generate a hologram. Secondly, the structure under test is stressed by the acoustic waves generated by a directly written acoustic transducer to generate a second hologram. Finally, the two holographic images are reconstructed to obtain the interference fringe patterns that can reveal the location of defects. The same procedures can be done using another optical metrology technique to compare the images with and without stress loading from acoustic waves generated by directly written acoustic transducers to detect defects.

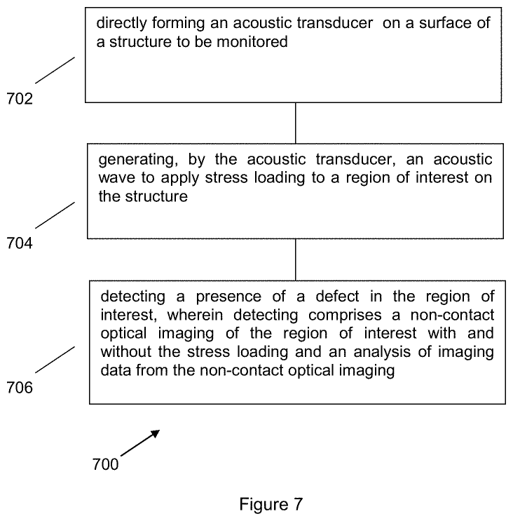

FIG. 7 shows a flow chart 700 illustrating a structural health monitoring method according to an example embodiment. At step 702, an acoustic transducer is directly formed, e.g. applicable over a large area by coating process, on a surface of a structure to be monitored. At step 704, an acoustic wave is generated by the acoustic transducer to apply stress loading to a region of interest on the structure. At step 706, a presence of a defect in the region of interest is detected. Detecting comprises a non-contact optical imaging of the region of interest with and without the stress loading and an analysis of imaging data from the non-contact optical imaging.

As described, proper design of directly written acoustic transducers in the present disclosure can enhance the acoustic energy at desired regions to enable sub-surface defect detection by non-contact optical imaging, which is not achievable with other loading methods such as thermal, vibration or vacuum loading. The proper design includes realizing constructive interference of acoustic waves for increasing the displacement; focusing acoustic energy at a particular location; forming a multi-element phased-array transducer with penetration depth tunable by controlling the time delay among the elements. Moreover, the direct writing of piezoelectric materials onto the structure under test by thermal spray or aerosol spray coating over a large area (approximately square-meter size) of the structure under test as described can avoid the tedious process of pasting or installing multiple discrete transducers at different locations to cover the large area. By combining proper designing and implementation of directly written acoustic transducers and direct large area full-field visualization of defects, e.g. by shearography, the present disclosure can realize fast (in approximately seconds) and direct inspection of sub-surface defects (possible for up to 10 mm depth) in various practical engineering structures. Furthermore, there is no limitation on the material or shape of the structures.

It will be appreciated by a person skilled in the art that numerous variations and/or modifications may be made to the present disclosure as shown in the specific embodiments without departing from the scope of the disclosure as broadly described. For example, the number of acoustic transducers may be varied depending on the monitoring requirements, e.g. size of the structure. Moreover, the geometries of the individual transducers may be selected based on the expected shape of the defect. The present embodiments are, therefore, to be considered in all respects to be illustrative and not restrictive.

1. A structural health monitoring method comprising:
directly forming at least one acoustic transducer on a surface of a structure to be monitored;
generating, by the at least one acoustic transducer, an acoustic wave to apply stress loading to a region of interest on the structure; and
detecting a presence of a defect in the region of interest, wherein detecting comprises a non-contact optical imaging of the region of interest with and without the stress loading and an analysis of imaging data from the non-contact optical imaging.

2. The method as claimed in claim 1, wherein directly forming the at least one acoustic transducer comprises:
directly forming a piezoelectric layer on the surface of the structure;
patterning a plurality of electrodes on the piezoelectric layer; and
selecting a periodicity of the electrodes based on a wavelength of the acoustic wave.

3. The method as claimed in claim 2, further comprising forming the plurality of electrodes as concentric curves, and selecting a center of the concentric curves to coincide with the region of interest.

4. The method as claimed in claim 1, wherein the at least one acoustic transducer comprises a phased-array transducer comprising a plurality of elements, and wherein generating the acoustic wave comprises controlling a time delay between the elements to tune a penetration depth of the acoustic wave in the region of interest.

5. The method as claimed in claim 4, wherein generating the acoustic wave further comprises activating selected elements of the plurality of elements.

6. The method as claimed in claim 1, further comprising directly forming a plurality of acoustic transducers on the surface of the structure and simultaneously generating a plurality of acoustic waves corresponding to the acoustic transducers to detect the presence of one or more defects.

7. The method as claimed in claim 2, wherein directly forming the piezoelectric layer on the surface of the structure comprises depositing a piezoelectric ceramic layer on the surface of the structure by a thermal spray process.

8. The method as claimed in claim 2, wherein directly forming the piezoelectric layer on the surface of the structure comprises depositing a piezoelectric polymer layer on the surface of the structure by an aerosol spray process.

9. The method as claimed in claim 1, wherein the non-contact optical imaging of the structure comprises shearography imaging.

10.-11. (canceled)

12. A structural health monitoring system comprising:
at least one acoustic transducer formed directly on a surface of a structure to be monitored;
a non-contact optical imaging device configured to image a region of interest on the structure; and
a processor communicatively coupled to the at least one acoustic transducer and the non-contact optical imaging device,
wherein the at least one acoustic transducer is configured to generate an acoustic wave to apply stress loading to the region of interest, and wherein the processor is configured to receive imaging data of the region of interest from the non-contact optical imaging device with and without the stress loading and to analyze the imaging data to detect a presence of a defect in the region of interest.

13. The system as claimed in claim 12, wherein the acoustic transducer comprises a piezoelectric layer and a plurality of electrodes patterned on the piezoelectric layer, and wherein a periodicity of the electrodes is selected based on a wavelength of the acoustic wave.

14. The system as claimed in claim 13, wherein the plurality of electrodes comprise concentric curves, and wherein a center of the concentric curves is selected to coincide with the region of interest.

15. The system as claimed in claim 12, wherein the at least one acoustic transducer comprises a phased-array transducer comprising a plurality of elements, and wherein the processor is further configured to control a time delay between the elements to tune a penetration depth of the acoustic wave in the region of interest.

16. The system as claimed in claim 15, wherein the processor is further configured to activate selected elements of the plurality of elements to generate the acoustic wave.

17. The system as claimed in claim 12, comprising a plurality of acoustic transducers directly formed on the surface of the structure and communicatively coupled to the processor, wherein the plurality of acoustic transducers are configured to simultaneously generate a plurality of acoustic waves to detect the presence of one or more defects.

18. The system as claimed in claim 12, wherein the piezoelectric layer comprises a piezoelectric ceramic layer.

19. The system as claimed in claim 12, wherein the piezoelectric layer comprises a piezoelectric polymer layer.

20. The system as claimed in claim 12, wherein the non-contact optical imaging device comprises one of a shearography imaging device, a holographic imaging device, or an optical metrology device.

21.-22. (canceled)
